(19) United States
(12) Patent Application Publication
(10) Pub. No.: US 2011/0068259 A1
(43) Pub. Date: Mar. 24, 2011

(54) APPARATUS AND METHOD FOR SENSING LIGHT PRODUCED BY PIXELS ON AN ELECTRONIC DISPLAY

(75) Inventor: Peter R. DALY, Yorktown Heights, NY (US)

(73) Assignee: Automated Media Services, Inc.

(21) Appl. No.: 12/887,146

(22) Filed: Sep. 21, 2010

Related U.S. Application Data
(60) Provisional application No. 61/244,374, filed on Sep. 21, 2009.

(51) Int. Cl. H01L 31/09; H01L 31/0232; H01L 31/18

(52) U.S. Cl. 250/227.29; 257/433; 438/65; 250/227.11; 257/E31.127

(57) ABSTRACT

An optical sensor package may include a chip carrier including a surface having edges defining corners. An optical sensor may be connected to the surface of the chip carrier and be positioned closer to one of the corners than any of the other corners.

### CROSS-REFERENCE TO RELATED APPLICATION

This Application for Letters Patent claims priority to co-pending U.S. Provisional Patent Application 61/244,374 filed Sep. 21, 2009, the entire contents of which are herein incorporated by reference in their entirety.

### BACKGROUND

Image sensor chips are generally used for sensing light intensity and light color. Applications may include sensing ambient light for brightness control of electronic devices. For example, a handheld device may sense brightness of ambient light and increase brightness when operating in a bright environment and decrease brightness in darker environments, thereby saving battery power and reducing overly bright light from the mobile device to better accommodate a user's eyes (i.e., display not too bright or dark). Other uses of image sensors include sensing colors in optical applications in which optical wavelengths, such as those separated by a prism, are to be measured and used for positioning measurements.

FIG. 1 is a block diagram showing a conventional configuration of an optical sensor chip 100 in which an optical sensor 102 is positioned in the center of a chip carrier 104. The chip carrier 104 is opaque. In one embodiment, the chip carrier package is an Intersil ISL29020 optical sensor package, a “6 Ld ODFN” configuration, that is a low power, high sensitivity, light-to-digital sensor with I²C interface, as provided on Intersil specification, and specifically the mechanical outline drawing of the package on page 11 of 11 of the Intersil specification. The optical sensor 102 is generally centered on a chip carrier 104, where the optical sensor 102 is horizontally centered on the chip carrier 104 and located 0.23 mm below center vertically on the chip carrier 104, as shown on page 14 of the Intersil specification. As shown, solder lead positions 106 are disposed symmetrically around the chip carrier 104. While the existing configuration provides for symmetry and simplifies production, the configuration causes more pixels than desired to be blocked when used to sense pixels on an electronic display. In other words, when using this type of sensor chip to sense a visual verification code directly from an electronic display, the optical sensor package 100 blocks many more pixels than are being sensed, thereby impacting the actual viewable area on the display and (i) affecting an image of a viewer or (ii) requiring more area of the electronic display to be covered by a housing than desired to block the sensor package. It should be understood that the same problem exists with other optical sensor packages and that the Intersil optical sensor package is illustrative of the problem.

### SUMMARY

The principles of the present invention provide for an optical sensor configuration is configured for atypical applications, such as sensing an optical verification signal displayed on an electronic display to provide minimal, if any, blockage of pixels on the electronic display. In minimizing pixel blockage by an optical sensor package, the principles of the present invention provide for (i) a chip carrier in which the optical sensor is positioned off-center vertically and/or horizontally, or (ii) use of a light tube that guides optical signals from pixels of the electronic display to the optical sensor positioned out-of-sight from a screen of the electronic display.

One embodiment of an optical sensor package includes a chip carrier including a surface having edges defining corners. An optical sensor may be connected to the surface of the chip carrier and be positioned closer to one of the corners than any of the other corners.

One embodiment of a method for forming an optical sensor package may include providing a chip carrier including a surface having edges defining corners. An optical sensor may be connected to the surface of the chip carrier closer to one of the corners than any of the other corners.

One embodiment of a method for positioning an optical sensor package on an electronic display may include providing an electronic display including a screen on which images are displayed. An optical sensor package with an optical sensor positioned closer to a corner of the optical sensor package than other corners may also be provided. An optical sensor package may be positioned in front of the screen of the electronic display with the corner toward which the optical sensor is positioned in front of pixels of the screen and the other corners of the optical sensor package may not being in front of pixels of the screen.

One embodiment of a method for using a light tube for guiding light from an electronic display to an optical sensor may include guiding optical signals from certain pixels of an electronic display to an optical sensor positioned outside an image area of the electronic display. The optical signals may be sensed by the optical sensor.

### BRIEF DESCRIPTION OF THE DRAWINGS

A more complete understanding of the method and apparatus of the principles of the present invention may be obtained by reference to the following Detailed Description when taken in conjunction with the accompanying Drawings herein:

FIG. 1 is an illustration of a conventional optical sensor package used for sensing light;

FIG. 2 is an illustration of an illustrative optical sensor package configured in accordance with the principles of the present invention;

FIG. 3 is a flow diagram of an illustrative process for configuring an optical sensor to sense an optical signal on an electronic display in accordance with the principles of the present invention on an electronic display;

FIGS. 4A-4B are illustrations of an illustrative light tube positioned in front of pixels of an electronic display for guiding light produced by pixels of the electronic display to an optical sensor for use in sensing an optical verification signal associated with content being displayed on the electronic display;

FIG. 5 is a flow diagram of an illustrative process for using a light tube for guiding light from an electronic display to an optical sensor;

FIGS. 6A and 6B are illustrations of an illustrative electronic display including respective housings that is configured to cover an optical sensor package or light tube that is used to sense optical signals from an area of pixels of the electronic display; and

FIG. 7 is a block diagram of an illustrative process for configuring an optical sensor package on an electronic display for use in sensing optical signals displayed by the electronic display.

### DETAILED DESCRIPTION

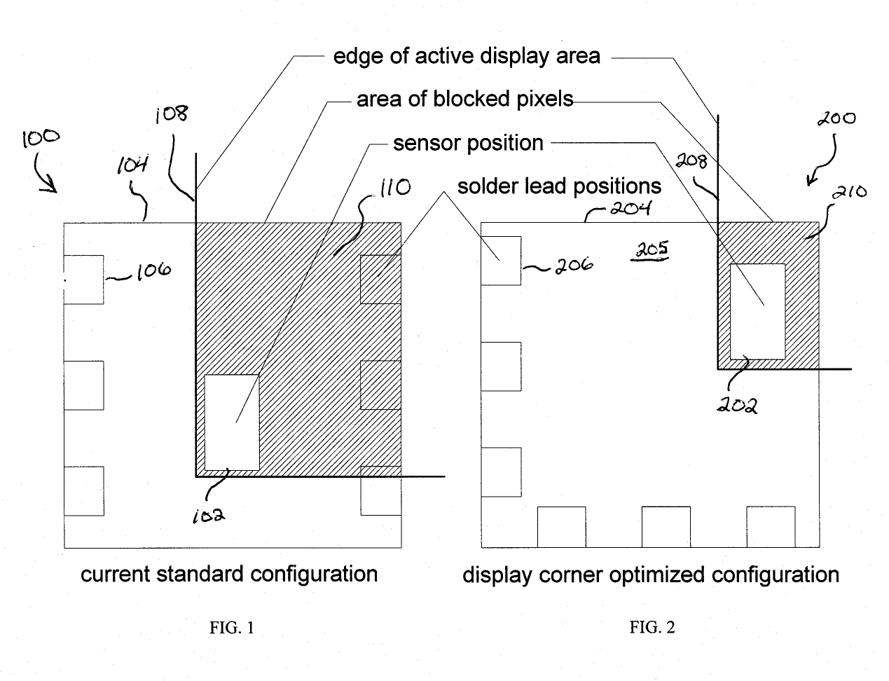

With regard to FIG. 2, an illustration of an alternative configuration of an optical sensor package 200 is shown. The optical sensor package 200 includes an optical sensor 202 and chip carrier 204. The optical sensor 202 is positioned near a corner of a surface 205 on which the optical sensor is attached, as opposed to being generally centered, as shown by the conventional optical sensor package 100 of FIG. 1.

By using the configuration of FIG. 2, the number of pixels being blocked by the optical sensor package 200 may be minimized. The reason for the reduced pixel blockage is that the closer to a corner of the chip carrier 204 that the optical sensor 202 is positioned within the optical sensor package 200, the less the optical sensor package 200 has to be positioned in front of the display portion of the electronic display, which results in a lower number of pixels being blocked.

As shown, in addition to aligning the optical sensor 202 close to a corner of the chip carrier 204, solder leads 206 are re-positioned (as compared to the positions of the solder leads 106 of FIG. 1) to be located along a different edge of the package 200, thereby allowing the sensor to be positioned closer to a corner of the package 200. It should be understood that the solder leads 206 may be positioned anywhere on the package 200 that would allow for the optical sensor 202 to be positioned close to a corner of the package 200. As an analogy, the optical sensor package 200 provides a “stamped postcard configuration,” where the sensor location is offset towards a corner of the package 200. In an alternative embodiment, rather than placing the optical sensor 202 in the corner of the package 200, the optical sensor may be positioned substantially closer to one end of the package 200 than the other. Such a configuration is not as effective as the stamped postcard configuration, but provides capabilities that are not available in conventional configurations where the optical sensor is disposed generally in the center of the package.

An electronic display 208 has an active display area 210 with pixels (not shown) that generate light, as understood in the art. The optical sensor 202 is shown to be positioned in the upper right corner of the package 200. The shaded region of the active display area 210 defines the area of blocked pixels by the optical sensor package 200. As a result of the repositioning of the optical sensor 202 on the chip carrier 204, the area of blocked pixels is greatly reduced as the sensing area is moved closer to the edge of the optical sensor package 200. Because the “image area” of any size electronic display is valuable and the package 200 optimizes the available space on the package 200, blockage of the valuable image area is minimized. And, because the solder leads 206 over-extend the edge of the package by some amount, the extra pad length allows for “filleting” of the solder after reflow, thereby adding strength to the solder joint. However, additional border blockage results from the solder lead edge of the substrate. With the positions of the solder leads 206 being positioned to an area outside the display area 210 of the electronic display 208, the extra pad length is no longer present, and, therefore reduces pixel blockage. In practice, the area around the display area 210 of the electronic display 208 includes a housing (not shown) that, when positioned, covers the optical sensor package 200, which, in part, covers pixels of the electronic display 208. By positioning the optical sensor 202 close to one corner, less of the display area 210 is covered by the housing. In other words, only one corner of the electronic display 208 has to cover pixels of the electronic display 208 and the other three corners may be outside the pixels of the electronic display 208. If the alternative configuration is used, then two corners of the optical sensor package 200 may cover pixels of the electronic display 208, but less area than if the optical sensor 202 were positioned generally in the center (i.e., vertically and horizontally centered) of the sensor package 200.

While the optical sensor 202 is shown to be a single sensor, it should be understood that the principles of the present invention provide for multiple optical sensors to be configured on the optical sensor package 200. Additional sensors may be positioned side-by-side, with or without spacing therebetween, and positioned closer to one corner, such as shown in FIG. 2. Alternatively, a single sensor, possibly larger than that shown, with the ability to have different areas of pixels be treated as separate sensors so that multiple optical signals (e.g., visual verification signals) displayed by different areas of pixels (e.g., two or more 5×5 sets of pixels) on the electronic display 208 may be sensed.

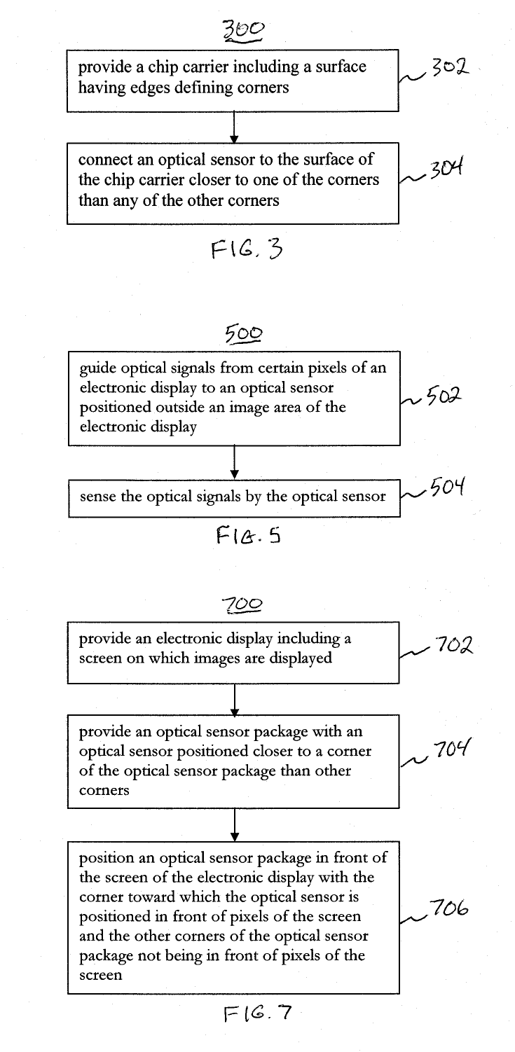

With regard to FIG. 3, a flow diagram of an illustrative process 300 for configuring an optical sensor on an electronic display in accordance with the principles of the present invention is shown. The process 300 starts at step 302, where a chip carrier including a surface having edges defining corners is provided. The chip carrier may be a conventional chip carrier, as understood in the art. In one embodiment, the chip carrier may be square or rectangular. However, alternative geometric shapes may be utilized. At step 304, an optical sensor may be connected to the surface of the chip carrier and closer to one of the corners than any of the other corners. The optical sensor may include one or more optical sensors.

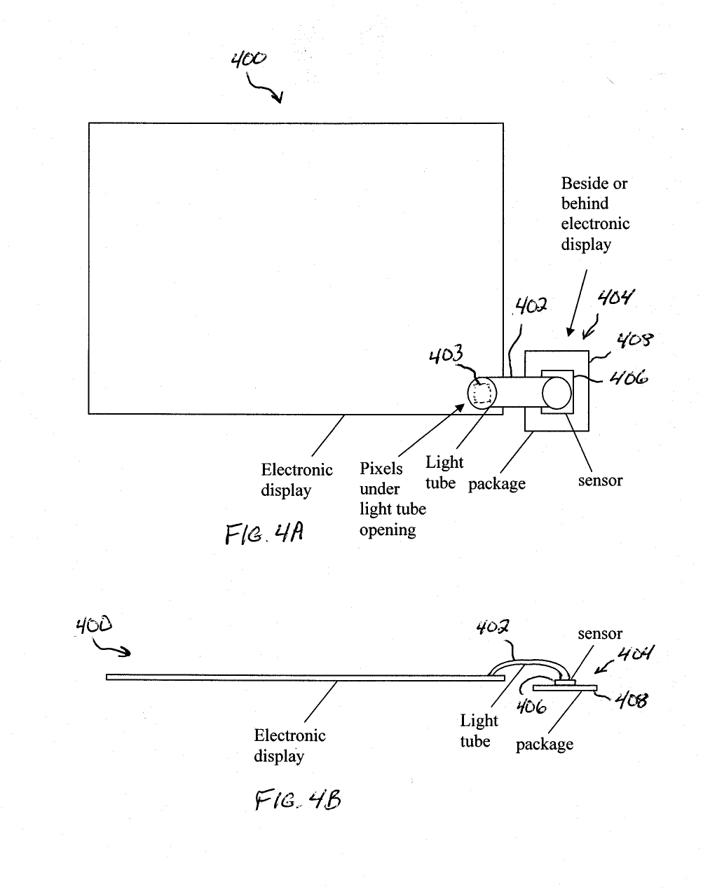

With regard to FIGS. 4A and 4B, illustrations of an electronic display configuration 400 including an illustrative light tube 402 positioned in front of pixels 403 of an electronic display for guiding light produced by pixels of the electronic display to an optical sensor package 404 may be used to sense an optical verification signal associated with content being displayed on the electronic display. The use of a light tube 402 in combination with a conventional optical sensor package 404 is an alternative embodiment to redesigning the light sensor package, as provided in FIG. 2. The light tube 402 may be utilized to guide light from specific pixels 403 on the electronic display to an optical sensor 406 mounted to a chip carrier 408. The optical sensor package 404 positioned to the side or behind of the electronic display.

As understood in the art, light tubes are generally used to route ambient light for lighting purposes in an indoor environment. Molded plastic light tubes are commonly used to conduct illumination from LEDs on a circuit board to buttons or through a housing to enable a user to view operation of the LEDs. In each of these cases, the light tubes are being used to enable a viewer to visually see the light of a lighting device (i.e., device to eye). According to the principles of the present invention, the light tube 402 routes the light produced by pixels of an electronic display to the optical sensor 406 that is used for sensing the intensity, color, and on/off operation of the pixels 403. The light tube 402 may be plastic, fiber, or any other material, as understood in the art, and be able to allow the light to be routed from in front of select pixels (e.g., 5×5, 50×50, or any other number of pixels of the electronic display) to illuminate the optical sensor 406 beside or behind the electronic display (e.g., mounted to the side of a casing of the electronic display or within the electronic display housing) so as to not block any pixels visible to viewers of the electronic display.

The light tube 402 may be temporarily or permanently affixed to the electronic display using a variety of techniques, including using temporary or permanent adhesives or mechanical configurations (e.g., mounting to the housing of the electronic display). In one embodiment, a lens (not shown), such as a microlens, may be utilized to focus the light of the pixels to be inserted into the light tube 402. By using the light tube 402, a conventional optical sensor package (See, for example, FIG. 1) may be used rather than a redesigned optical sensor package (See, for example, FIG. 2) as the optical sensor package would not be positioned in front of the electronic display. In one embodiment, the optical sensor is positioned within a housing of the electronic display.

With regard to FIG. 5, a flow diagram of an illustrative process 500 for using a light tube for guiding light from an electronic display to an optical sensor is shown. The process 500 starts at step 502, where an electronic display including a screen on which images are displayed is provided. At step 504, an optical sensor package with an optical sensor positioned closer to a corner of the optical sensor package than other corners is provided. It should be understood that the optical sensor may include one or more optical sensors. At step 506, an optical sensor package may be positioned in front of the screen of the electronic display with the corner toward which the optical sensor is positioned in front of pixels of the screen and the other corners of the optical sensor package not being positioned in front of pixels of the screen. By configuring the optical sensor package as described in the process 500, a housing of the electronic display may be reduced in size, thereby providing for additional viewable pixel area on the screen of the electronic display. If the screen is three inches, then display area matters more than a screen that is 15 inches. However, the more display area that can be viewed, the more content that can be shown and the less distraction that exists for the viewers.

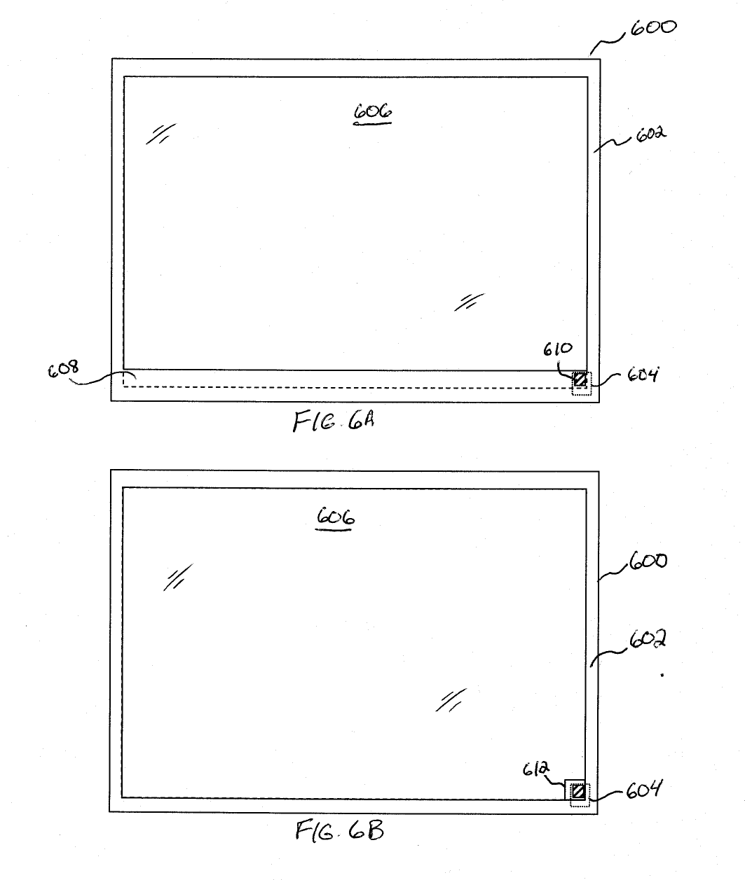

With regard to FIG. 6A, an illustration of an illustrative electronic display 600 with a housing 602 configured to shield an optical sensor package 604 or light tube (not shown) from being viewed by a viewer viewing a screen 606 of the electronic display 600 is shown. A hidden screen area 608 of the screen 606 is prevented from being viewed as a result of the housing 602. As shown, a pixel region 610 in which a visual verification signal may be displayed may be sensed by an optical sensor (not shown) positioned in the upper left corner (from the perspective of the front of the electronic display 600) of the optical sensor package 604 is positioned in front of the pixel region 610. Because the optical sensor is positioned in the corner of the optical sensor package 604, the amount of space over which the housing 602 covers the screen 606 is less than that had the optical sensor been generally centered on the optical sensor package 604.

With regard to FIG. 6B, rather than having the housing extend over the optical sensor as shown in FIG. 6A, the housing includes a sensor cover region 612 that covers the optical sensor package 604. The sensor cover region 612 is shown to be rectangular. However, it should be understood that the sensor cover region 612 may be any other shape. In addition, rather than being part of the housing 602, the sensor cover region 612 may be a separate structure that is connected to the housing 602. For the purposes of this application, the housing 602 includes the sensor cover region 612, whether being formed with or having a separate structure attached. As shown, the optical sensor package has only the upper left corner positioned over the screen, thereby minimizing the amount of screen that has to be covered by the housing.

As a result of using the principles of the present invention, visual verification signals that represent information associated with content being displayed may be measured and minimize the amount of area of a screen of an electronic display that has to be covered by a portion of a housing so that viewers do not see an optical sensor package or light tube. In one embodiment, the housing has a geometric shape (e.g., square, rectangle) for use in providing a border for the screen of the electronic display, and the optical sensor package or light tube is shielded from being viewed by viewers. In another embodiment, the housing has a geometric shape (e.g., square, rectangle), but a portion of the housing (e.g., tab) extends in front of the screen to shield the optical sensor package or light tube from being viewed by viewers.

With regard to FIG. 7, a block diagram of an illustrative process 700 for configuring an optical sensor package on an electronic display for use in sensing optical signals displayed by the electronic display is provided. The process 700 starts at step 702, where an electronic display including a screen on which images are displayed is provided. At step 704, an optical sensor package with an optical sensor positioned closer to a corner of the optical sensor package than other corners is provided. At step 706, an optical sensor package may be positioned in front of the screen of the electronic display with the corner toward which the optical sensor is positioned in front of pixels of the screen and the other corners of the optical sensor package not being in front of pixels of the screen, such as shown in FIGS. 6A and 6B.

The previous detailed description of a small number of embodiments for implementing the invention is not intended to be limiting in scope. One of skill in this art will immediately envisage the methods and variations used to implement this invention in other areas than those described in detail.

What is claimed:

1. An optical sensor package, comprising:
a chip carrier including a surface having edges defining corners; and
an optical sensor connected to the surface of said chip carrier and positioned closer to one of the corners than any of the other corners.

2. The optical sensor package according to claim 1, wherein said chip carrier further includes solder lead positions configured in non-symmetric positions about edges of said chip carrier.

3. The optical sensor package according to claim 2, wherein the solder lead positions are positioned along two sides of the surface of said chip carrier.

4. The optical sensor package according to claim 1, wherein said chip carrier is opaque.

5. A method for forming an optical sensor package, comprising:
providing a chip carrier including a surface having edges defining corners; and
connecting an optical sensor to the surface of the chip carrier closer to one of the corners than any of the other corners.

6. The method according to claim 5, further comprising positioning the solder leads in non-symmetric positions about edges of the chip carrier.

7. The method according to claim 6, wherein positioning the sold leads includes positioning the solder leads along two sides of the surface of the chip carrier.

8. A method for positioning an optical sensor package on an electronic display, said method comprising:
providing an electronic display including a screen on which images are displayed;
providing an optical sensor package with an optical sensor positioned closer to a corner of the optical sensor package than other corners; and
positioning an optical sensor package in front of the screen of the electronic display with the corner toward which the optical sensor is positioned in front of pixels of the screen and the other corners of the optical sensor package not being in front of pixels of the screen.

9. The method according to claim 8, further comprising positioning a housing of the electronic display in front of the other corners of the optical sensor package.

10. A method for using a light tube for guiding light from an electronic display to an optical sensor, said method comprising:
guiding optical signals from certain pixels of an electronic display to an optical sensor positioned outside an image area of the electronic display; and
sensing the optical signals by the optical sensor.

11. The method according to claim 10, wherein guiding optical signals from certain pixels includes using a light tunnel to guide the optical signals.

12. The method according to claim 10, further comprising attaching a light tunnel to a screen of the electronic display in front of the certain pixels.

13. The method according to claim 10, further comprising positioning the optical sensor within a housing of the electronic display.
